(19) United States
(12) Patent Application Publication
(10) Pub. No.: US 2003/0160335 A1
(43) Pub. Date: Aug. 28, 2003

(54) FLIP CHIP INTERCONNECTION STRUCTURE AND FABRICATION PROCESS THEREOF

(76) Inventors: HO-MING TONG, TAIPEI (TW); CHUN-CHI LEE, KAOHSIUNG (TW); JEN-KUANG FANG, PINGTUNG HSIEN (TW); MIN-LUNG HUANG, KAOHSIUNG (TW); JAU-SHOUNG CHEN, HSINCHU HSIEN (TW); CHING-HUEI SU, KAOHSIUNG (TW); CHAO-FU WENG, TAINAN (TW); YUNG-CHI LEE, KAOHSIUNG (TW); YU-CHEN CHOU, KAOHSIUNG (TW); TSUNG-HUA WU, KAOHSIUNG HSIEN (TW); SU TAO, KAOHSIUNG (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,466

(22) Filed: Jan. 22, 2003

(30) Foreign Application Priority Data
Feb. 27, 2002 (TW) 91103528

(51) Int. Cl. H01L 23/48

(52) U.S. Cl. 257/778

(57) ABSTRACT

A flip chip interconnection structure is formed over the active surface of a chip. The active surface of the chip includes a plurality of bonding pads. A redistribution trace layer, including at least a redistribution trace, is formed over the active surface in a manner to electrically connect to the bonding pads. A plurality of conductive posts, made of a tin-lead alloy having a tin to lead ratio greater than about 10:90, are formed on and connected to the redistribution trace structure. An insulating layer is formed over the redistribution trace layer to encompass the conductive posts. The insulating layer comprises a plurality of openings through which the conductive posts externally protrude.

### CROSS REFERENCE TO RELATED APPLICATIONS

This application claims the priority benefit of Taiwan application serial no. 91103528, filed on Feb. 27, 2002.

### BACKGROUND OF INVENTION

1. Field of the Invention

The invention relates generally to a flip chip interconnection structure and, more particularly, to a flip chip interconnection structure and a flip chip interconnection process that form conductive posts of a specific metal alloy that allows simplification of the flip chip interconnection structure.

2. Description of the Related Art

A flip chip interconnection structure conventionally consists of mounting and electrically connecting the chip to the substrate through conductive bumps that are formed on the bonding pads of the chip. Compared to the wire bonding and tape automatic bonding (TAB) techniques, the flip chip interconnection structure provides short electrical paths and good electrical connection properties. Furthermore, by exposing the bare rear surface of the chip, the heat dissipating performance of the package can be improved.

Referring to FIG. 1 through FIG. 6, various schematic views illustrate a bump fabricating process for a flip chip interconnection structure known in the prior art. As illustrated in FIG. 1, the fabricating process of the prior art starts with the provision of a substrate 110, typically a semiconductor wafer, having an active surface 112. The active surface 112 is covered with a passivation layer 114 that exposes a plurality of bonding pads 116 through openings 118 (only one is illustrated). An adhesive layer 120 is formed on the active surface 112 via sputtering. Via photolithography, etching, and plating processes, a redistribution trace 130 is formed on the adhesive layer 120. Thereafter, a photoresist layer 140 is formed on the adhesive layer 120 and the redistribution trace 130. The photoresist layer 140 then is exposed and developed to form a plurality of openings 142 (only one is shown) that expose the redistribution trace 130.

As illustrated in FIG. 2, a conductive post 150 is subsequently formed in the opening 142 by plating. The conductive post 150 is electrically connected to the redistribution trace 130, and is usually made of copper. A barrier layer 160 then is formed on the conductive post 150, as illustrated in FIG. 3. The photoresist layer 140 then is removed. The exposed regions of the adhesive layer 120 are subsequently removed, and only regions of the adhesive layer 120 underlying the redistribution trace 130 remain (see FIG. 4). At this stage, the passivation layer 112 is externally exposed (see FIG. 5).

Referring to FIG. 6, an insulating layer 170 is formed over the redistribution trace 130 and the active surface 112 via liquid molding. The insulating layer 170 includes an opening 172 through which the conductive post 150 protrudes with the barrier layer 160 externally exposed.

A major disadvantage of the above process of the prior art is that the copper conductive post easily oxidizes. The fabrication process therefore has to be performed under substantially oxygen-free conditions. Copper being relatively elastic and easily diffusing, the conductive post therefore is easily subject to deformation, and the formation of the barrier layer is required to prevent copper diffusion. As a result, the fabrication cost is increased.

### SUMMARY OF INVENTION

An aspect of the invention is therefore to provide a flip chip interconnection structure and a fabrication process thereof in which the conductive posts are made of an adequate material that provides better physical properties, simplifies the flip chip interconnection structure, and reduces the fabrication cost.

To accomplish the above and other objectives, a flip chip interconnection structure of the invention is formed on an active surface of a chip. The active surface of the chip includes a plurality of bonding pads. A redistribution trace structure, including at least a redistribution trace layer, is formed over the active surface in a manner to electrically connect to the bonding pads. A plurality of conductive posts are formed on and connected to the redistribution trace structure. An insulating layer is formed over the redistribution trace structure to encompass the conductive posts. The insulating layer comprises a plurality of openings through which the conductive posts externally protrude. The conductive posts are made of a tin-lead alloy having a tin to lead ratio greater than about 10:90.

According to a preferred embodiment of the invention, the conductive posts preferably protrude over the insulating layer with a height between about 75 μm and 500 μm. Furthermore, the tin to lead ratio of the conductive posts is preferably 10Sn/90Pb, 5Sn/95Pb, or 3Sn/97Pb.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 through FIG. 6 are schematic views illustrating a fabrication process of a flip chip interconnection structure known in the prior art; and

FIG. 7 through FIG. 16 are schematic views illustrating a fabrication process of a flip chip interconnection structure according to an embodiment of the invention.

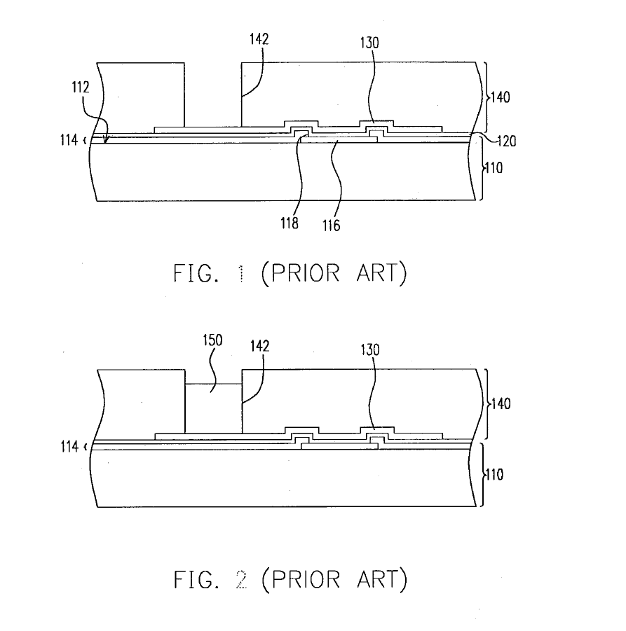

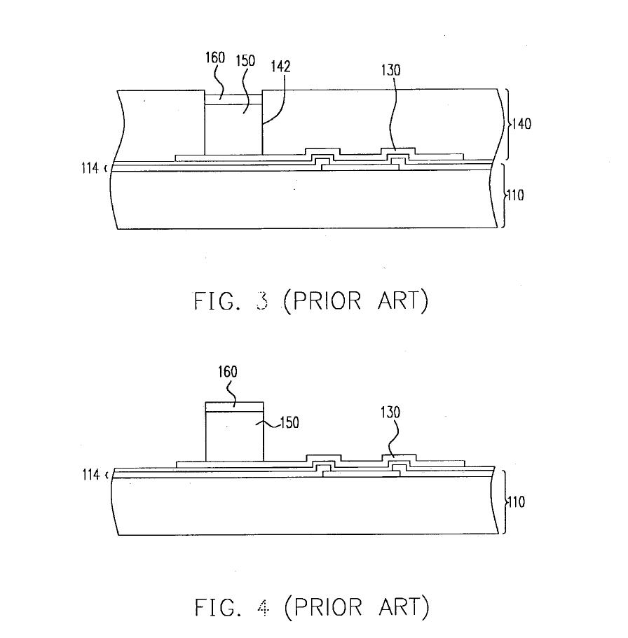

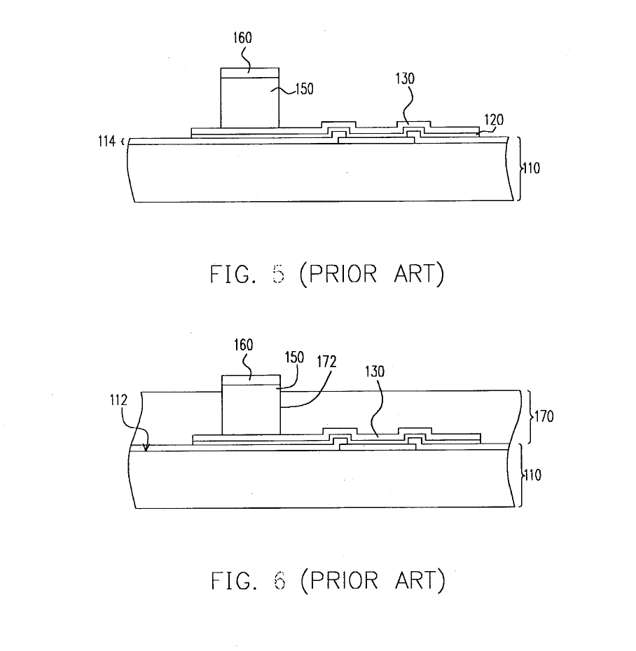

### DETAILED DESCRIPTION

The following detailed description of the embodiments and examples of the present invention with reference to the accompanying drawings is only illustrative and not limiting. Furthermore, wherever possible in the description, the same reference symbols will refer to similar elements and parts unless otherwise illustrated in the drawings.

Reference now is made to FIG. 7 through FIG. 16 to describe the fabrication process of a flip chip interconnection structure according to an embodiment of the invention. As illustrated in FIG. 7, a substrate 210, for example a semiconductor wafer or a chip, is provided with a plurality of bonding pads 216 (only one bonding pad is illustrated for the sake of simplification) formed on an active surface 212 of the substrate 210. A passivation layer 214 covers the active surface 212, and includes an opening 218 that exposes the bonding pad 216.

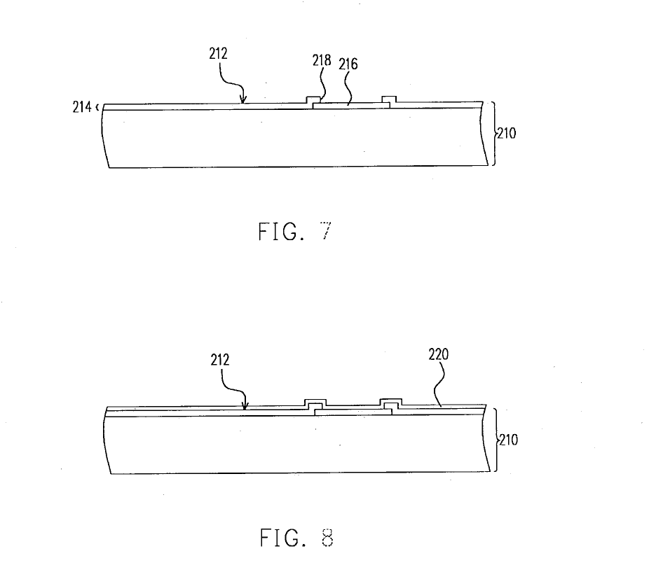

Referring to FIG. 8, an adhesive layer 220 is formed over the active surface 212. The adhesive layer 220 is made of, for example, titanium, titanium-tungsten alloy, chromium, etc.

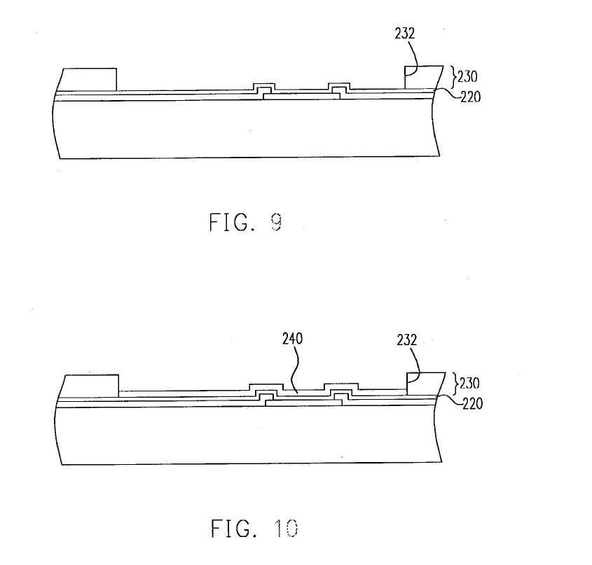

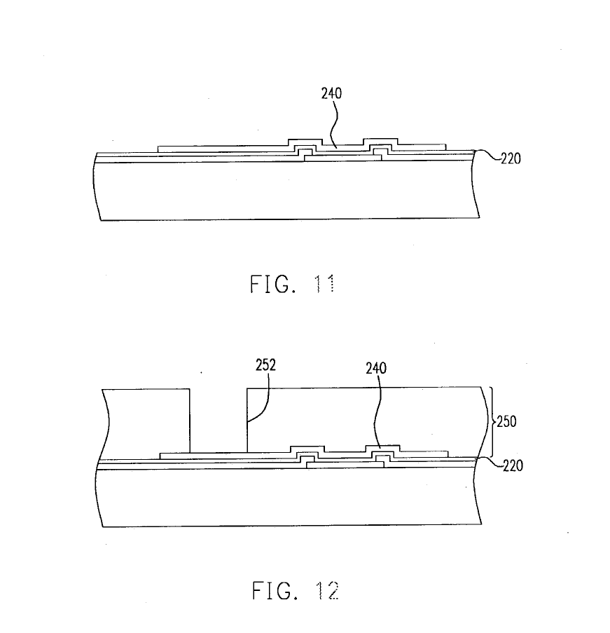

Referring to FIG. 9, a photolithography process is performed. After a photoresist layer 230 has been formed on the adhesive layer 220, a redistribution trace pattern is transferred to the photoresist layer 230 through an exposure step. The photoresist layer 230 then is developed to form a plurality of openings 232 corresponding to the locations where the formation of the redistribution trace layer is desired (only one opening is illustrated). Via plating, the redistribution trace layer 240 is formed in the opening 232 of the photoresist layer 230 in a manner to electrically connect the adhesive layer 220, as illustrated in FIG. 10. The redistribution trace layer 240 is made of, for example, copper or aluminum. As illustrated in FIG. 11, the photoresist layer 230 is subsequently removed to expose the adhesive layer 220.

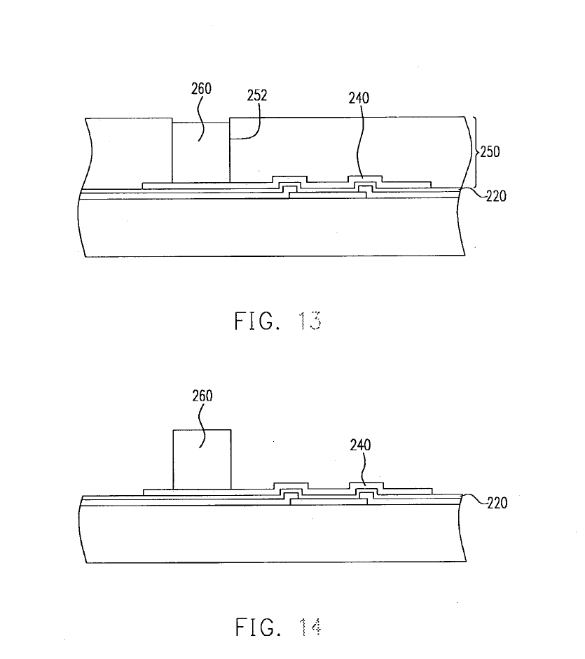

Referring to FIG. 12, another photoresist layer 250 is formed on the adhesive layer 220 and redistribution trace layer 240. Via an exposure step, the pattern of a conductive post is transferred to the photoresist layer 250. The photoresist layer 250 then is developed to form an opening 252 at the location where the conductive post is to be formed. By plating, the conductive post 260 is formed in the opening 252, being electrically connected to the redistribution trace layer 240, as illustrated in FIG. 13. According to the invention, the conductive post 260 is preferably made of a solder material having a high lead content such as, for example, a tin-lead alloy of high lead content such as 10Sn/90Pb, 5Sn/95Pb, or 3Sn/97Pb. “High lead content” herein will be understood as a tin to lead ratio preferably greater than about 10:90. The photoresist layer 250 is subsequently removed from the adhesive layer 220 and the redistribution trace layer 240, which partially exposes the adhesive layer 220 and the redistribution trace layer 240, as shown in FIG. 14.

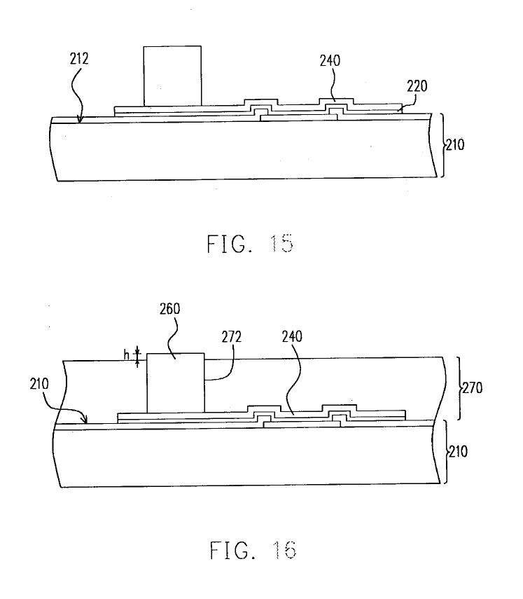

Referring to FIG. 15, the exposed regions of the adhesive layer 220 are removed, and only the regions of the adhesive layer 220 that underlie the redistribution trace layer 240 remain. At this stage, the passivation layer 214 is also exposed.

Referring to FIG. 16, an insulating layer 270 is formed via liquid molding in a manner to encompass the redistribution trace layer 240 and the conductive post 260 over the active surface 212. Liquid molding is performed via, for example, arranging an annular plate (not shown) on the substrate 210 to cover its periphery. A liquid or semi-melted polymer is filled through the annular plate in a manner to cover the active surface 212 and the redistribution trace layer 240. Due to the presence of the annular plate, the polymer does not flow out of the annular plate. The polymer then undergoes a solidification step to form the insulating layer 270, after which the annular plate is removed. The insulating layer 270 thereby formed includes an opening 272 through which the conductive post 260 protrudes a height “h” over the insulating layer 270, h being between about 75 μm to 200 μm.

The specific use of a tin-lead alloy with a high lead content for the conductive post 260 provides several advantages. First, oxidation and corrosion problems are favorably overcome, which facilitates the fabrication process of the conductive post 260. Being more rigid, the conductive post 260 is not easily deformed even if it is dimensionally thinner. Furthermore, tin-lead alloy does not easily diffuse. Conventional plating of a barrier layer on the conductive post therefore is not needed.

It will be understood that the invention as described above may be suitable for different materials of the redistribution trace layer and adhesive layer. For example, any materials that can provide a sufficient bondability with the active surface of the substrate may be suitable for the adhesive layer. Furthermore, the redistribution trace layer may be constructed according to a redistribution trace structure having multi-layered traces inside the insulating layer body.

It should be apparent to those skilled in the art that other structures that are obtained from various modifications and variations of different parts of the above-described structures of the invention would be possible without departing from the scope and spirit of the invention as illustrated herein. Therefore, the above description of embodiments and examples only illustrates specific ways of making and performing the invention that, consequently, should cover variations and modifications thereof, provided they fall within the inventive concepts as defined in the following claims.

1. A flip chip interconnection structure, comprising:
a chip, having an active surface on which are formed a plurality of bonding pads;
a redistribution trace layer, formed over the active surface of the chip and electrically connected to the bonding pads; a plurality of conductive posts, formed on and electrically connected to the redistribution trace layer, the conductive posts being made of a solder alloy; and
an insulating layer, formed over the redistribution trace layer, the insulating layer including a plurality of openings through which the conductive posts protrude over the insulating layer.

2. The flip chip interconnection structure of claim 1, wherein the conductive posts have a tin to lead ratio that is 10Sn/90Pb, 5Sn/95Pb, or 3Sn/97Pb.

3. The flip chip interconnection structure of claim 1, wherein the conductive posts are made of a tin-lead alloy with a tin to lead ratio greater than about 10:90.

4. The flip chip interconnection structure of claim 1, wherein the conductive posts protrudes over the insulation layer with a height of about 75 μm to 200 μm.

5. The flip chip interconnection structure of claim 1, wherein the conductive post has a tin to lead ratio of 10Sn/90Pb, 5Sn/95Pb, and 3Sn/97Pb.

6. A flip chip interconnection structure comprising:
a chip, having an active surface;
a conductive post, formed over the active surface, the conductive post being made of a tin-lead alloy; and
an insulating layer, located over the active surface of the chip and having an opening through which the conductive post protrudes over the insulating layer.

7. The flip chip interconnection structure of claim 6, wherein the conductive posts are made of a tin-lead alloy with a tin to lead ratio greater than about 10:90.

8. The flip chip interconnection structure of claim 6, wherein the conductive post has a tin to lead ratio of 10Sn/90Pb, 5Sn/95Pb, and 3Sn/97Pb.

9. The flip chip interconnection structure of claim 6, further comprising a redistribution trace layer that is formed between the active surface of the chip and the insulating layer, the redistribution trace layer including a redistribution trace that is electrically connected to the bonding pad.

10. The flip chip interconnection structure of claim 6, wherein the conductive post protrudes over the insulating layer with a height between about 75 μm and 200 μm.

11. A fabrication process of a flip chip interconnection structure, comprising:
providing a chip having an active surface on which are formed a plurality of bonding pads;
forming a redistribution trace layer over the active surface of the chip and electrically connected to the bonding pads;
forming a plurality of conductive posts on the redistribution trace layer, the conductive posts being made of a tin-lead alloy; and
forming an insulating layer over the redistribution trace layer, the insulating layer encompassing the conductive posts.

12. The fabrication process of claim 11, wherein the conductive posts are made of a tin-lead alloy with a tin to lead ratio greater than about 10:90.

13. The fabrication process of claim 11, wherein the conductive posts are made of a material that is selected from a group consisting of 10Sn/90Pb tin-lead alloy, 5Sn/95Pb tin-lead alloy, and 3Sn/97Pb tin-lead alloy.

14. A fabrication process of a flip chip interconnection structure, comprising:
providing a chip having an active surface;
forming a plurality of conductive posts over the active surface of the chip, the conductive posts being made of a tin-lead alloy; and
forming an insulating layer over the active surface of the chip to encompass the conductive posts.

15. The fabrication process of claim 14, wherein the conductive posts are made of a tin-lead alloy with a tin to lead ratio greater than about 10:90.

16. The fabrication process of claim 14, wherein the conductive posts are made of a material that is selected from a group consisting of 10Sn/90Pb tin-lead alloy, 5Sn/95Pb tin-lead alloy, and 3Sn/97Pb tin-lead alloy.

17. The fabrication process of claim 14, further comprising forming a redistribution trace layer over the active surface of the chip before forming the conductive posts, wherein the conductive posts are formed on the redistribution trace layer.

18. The fabrication process of claim 14, wherein the conductive posts protrude over the insulating layer with a height between about 75 μm and 200 μm.
